(19) United States
(12) Patent Application Publication
(10) Pub. No.: US 2026/0036612 A1
(43) Pub. Date: Feb. 5, 2026

(54) SIMULATING MULTI-DIRECTIONAL MOBILITY INSIDE A RADIO FREQUENCY CHAMBER THROUGH BELT-DRIVEN MOVEMENT SYSTEMS

(71) Applicant: T-Mobile USA, Inc., Bellevue, WA (US)

(72) Inventors: Eric Gordon Copping Christie, Lynnwood, WA (US); Jacob Andrew Fontana, Bellevue, WA (US)

(21) Appl. No.: 18/791,204

(22) Filed: Jul. 31, 2024

(51) Int. Cl. G01R 29/08; G01R 29/10

(52) U.S. Cl. CPC G01R 29/0821; G01R 29/105

(57) ABSTRACT

Various implementations generally relate to systems and methods for simulating movement of multiple wireless devices inside an RF testing chamber. Internal surfaces of the RF testing chamber are covered with a radiation absorbent material. Multiple belt-driven movement systems including a belt and a holder component are affixed inside the RF testing chamber, and a wireless device is attached to each holder component of each belt-driven movement system. The wireless devices are enabled to move in a direction along the orientation of each belt-driven movement system by controlling a motor of each belt-driven movement system to simulate multi-directional mobility inside the RF testing chamber.

### BACKGROUND

An anechoic chamber is a room designed to stop reflections or echoes of either sound or electromagnetic waves. A radio frequency (RF) anechoic chamber, also known as an RF chamber, is a specialized enclosure designed to provide a controlled and shielded environment for testing and measuring RF devices. Interior surfaces of the RF chamber are covered with radiation absorbent material (RAM) to absorb incident RF radiation from as many incident directions as possible. The more effective the RAM, the lower the resulting level of reflected RF radiation.

### BRIEF DESCRIPTION OF THE DRAWINGS

Detailed descriptions of implementations of the present invention will be described and explained through the use of the accompanying drawings.

FIG. 1A is a diagram that illustrates a layout of belt-driven movement systems positioned inside a radio frequency (RF) chamber, according to some implementations.

FIG. 1B is a diagram that illustrates a side view of the belt-driven movement systems positioned inside an RF chamber, according to some implementations.

FIG. 2A illustrates an assembly of a holder component, according to some implementations.

FIG. 2B illustrates a wireless device attached to the holder component, according to some implementations.

FIG. 3 is a diagram of a motor that can be utilized in a belt-driven movement system, according to some implementations.

FIG. 4 is a diagram of a turnbuckle-mounted timing pulley that can be utilized in a belt-driven movement system, according to some implementations.

FIG. 5 is a system diagram illustrating interconnection of the belt-driven movement systems and an external control device, according to some implementations.

FIG. 6 is a flowchart illustrating a representative process to drive one-directional movements of wireless devices to simulate multi-directional mobility inside the RF chamber, according to some implementations.

FIG. 7 is a block diagram that illustrates an example of a computer system in which at least some operations described herein can be implemented.

The technologies described herein will become more apparent to those skilled in the art from studying the Detailed Description in conjunction with the drawings. Embodiments or implementations describing aspects of the invention are illustrated by way of example, and the same references can indicate similar elements. While the drawings depict various implementations for the purpose of illustration, those skilled in the art will recognize that alternative implementations can be employed without departing from the principles of the present technologies. Accordingly, while specific implementations are shown in the drawings, the technology is amenable to various modifications.

### DETAILED DESCRIPTION

Radio frequency (RF) chambers currently available are not suitable for conducting tests for beamforming and switching involving multiple wireless devices. To overcome the limitations of existing RF chambers, the disclosed technologies utilize belt-driven movement systems within an RF chamber to drive one-directional movements of wireless devices to simulate multi-directional mobility inside the RF chamber.

In an embodiment, an RF chamber includes multiple belt-driven movement systems oriented horizontally, vertically, or diagonally relative to the floor of the RF chamber. Each belt-driven movement system includes a holder component that enables attachment of a wireless device and a belt that enables movement of the attached wireless device along the orientation of the belt-driven movement system. Each belt-driven movement system also includes a controllable motor that is configured to control movement of the belt based on a control signal received from an external control device.

The description and associated drawings are illustrative examples and are not to be construed as limiting. This disclosure provides certain details for a thorough understanding and enabling description of these examples. One skilled in the relevant technology will understand, however, that the invention can be practiced without many of these details. Likewise, one skilled in the relevant technology will understand that the invention can include well-known structures or features that are not shown or described in detail to avoid unnecessarily obscuring the descriptions of examples.

### Simulating Multi-Directional Mobility Inside an RF Chamber Through Belt-Driven Movement Systems

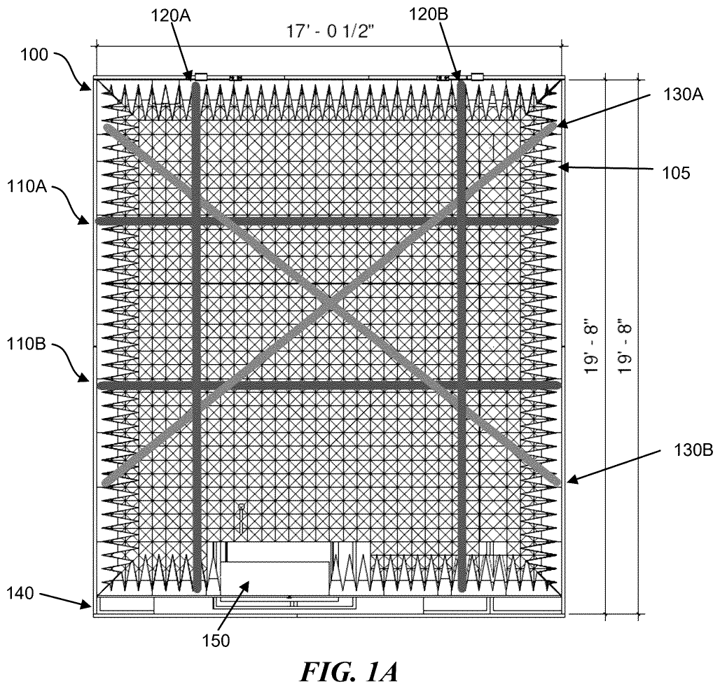

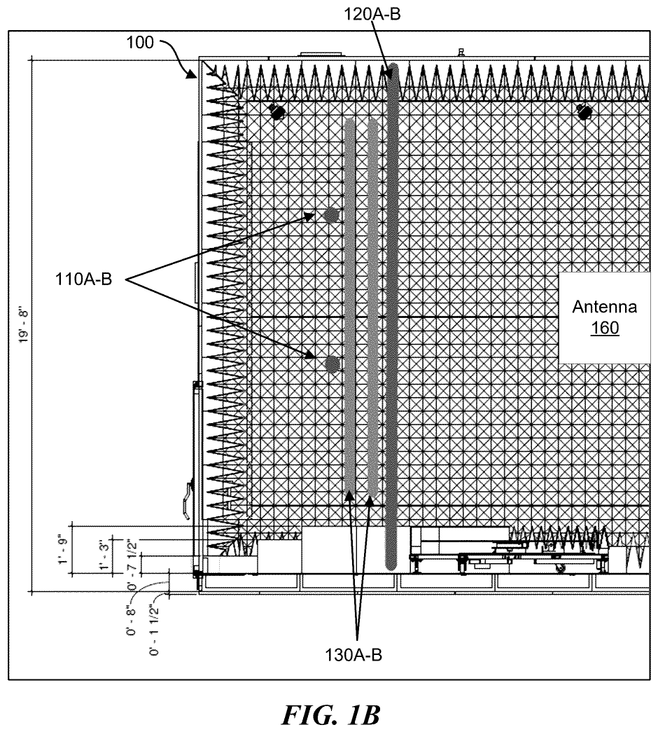

FIG. 1A is a diagram that illustrates a layout of belt-driven movement systems positioned inside an RF chamber 100, according to some implementations. The RF chamber 100, as illustrated in FIG. 1, has a height of 19 ft. 8 in. and a width of 17 ft. ½ in., but the dimensions of the RF chamber 100 can vary depending on frequencies used in beamforming tests. For example, beamforming tests involving lower radiated frequencies require larger RF chambers compared to beamforming tests involving higher radiated frequencies because waves of lower frequencies have longer wavelengths and are lower in energy compared to waves of higher frequencies.

The RF chamber 100 includes multiple radiation absorbent material (RAM) 105 that covers internal surfaces of the RF chamber 100. The RAM 105 is designed and shaped to absorb incident RF radiation from incoming incident directions. An example RAM 105 comprises arrays of pyramid-shaped pieces. Each pyramid-shaped piece can be installed on the internal surfaces of the RF chamber such that the tip of the pyramid-shaped piece points inward to the center of the RF chamber. The RAM 105 is constructed from lossy dielectric material to effectively reduce reflections and other unwanted signals arising from test setup, such as signals generated by metallic surfaces of test equipment placed inside the RF chamber. In some embodiments, in order to reduce unwanted signals, sections of RAM 105 are temporarily removed to install test equipment and replaced to cover the test equipment before performing beamforming tests.

In some embodiments, the RAM 105 comprises a rubberized foam material impregnated with controlled mixtures of carbon and iron. The size and material makeup of each piece of RAM 105 can vary depending on the lowest expected frequency and the amount of absorption required for a beamforming test.

The RF chamber 100 can include one or more horizontally oriented belt-driven movement systems 110A-B, one or more vertically oriented belt-driven movement systems 120A-B, and one or more diagonally oriented belt-driven movement systems 130A-B. The orientations of the belt-driven movement systems are relative to a floor 140 of the RF chamber 100. In some embodiments, the RF chamber 100 is configured to include at least six belt-driven movement systems.

Each belt-driven movement system includes a belt that traverses across the RF chamber 100, as illustrated in FIG. 1A. Each belt-driven movement system can include a controllable motor that is configured to control movement of the belt along the orientation based on a control signal received from an external control device. The motor can be positioned on one end of the belt-driven movement system and disposed on a wall of the RF chamber 100 adjacent to the RAM 105. A pulley can be positioned on the other end of the belt-driven movement system and disposed on an opposite wall of the RF chamber 100 adjacent to the RAM 105. The belt can be looped over the motor and the pulley to maintain a desired belt tension. In some embodiments, the belt includes a jagged profile on one side and a flat profile on another side such that loose ends of the belt can be fixed onto each other via the jagged profile.

Each belt-driven movement system includes a holder component that is fixably connected to the belt. A wireless device is attachable to the holder component such that moving the belt along the orientation of the belt-driven movement system moves the wireless device along the orientation of the belt-driven movement system. As illustrated in FIG. 1A, the RF chamber 100 can include six wireless devices each attached to the holder component of each belt-driven movement system. In some embodiments, the motor of each belt-driven movement system includes a bracket configured to maintain a belt tension to hold the wireless device in an upright position.

The floor 140 can include a platform 150 to place antennas to be used for beamforming tests. In an embodiment, the height of the platform 150 is less than or equal to the height of the RAM 105 to reduce unwanted signals generated from waves that are reflected from the platform 150. Alternatively, or additionally, the platform 150 can be configured to have non-conductive plastic or wooden surfaces to reduce unwanted reflections.

FIG. 1B is a diagram that illustrates a side view of the belt-driven movement systems positioned inside an RF chamber 100, according to some implementations. An antenna 160 capable of beamforming can be positioned inside the RF chamber 100 to configure desired antenna radiation patterns and electromagnetic interference at each belt-driven movement system.

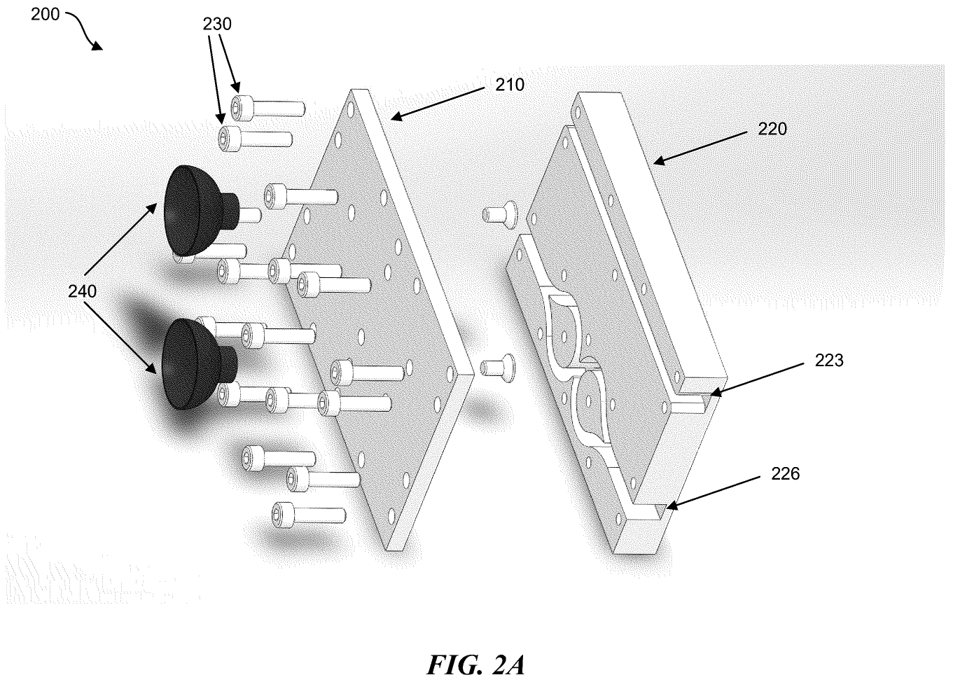

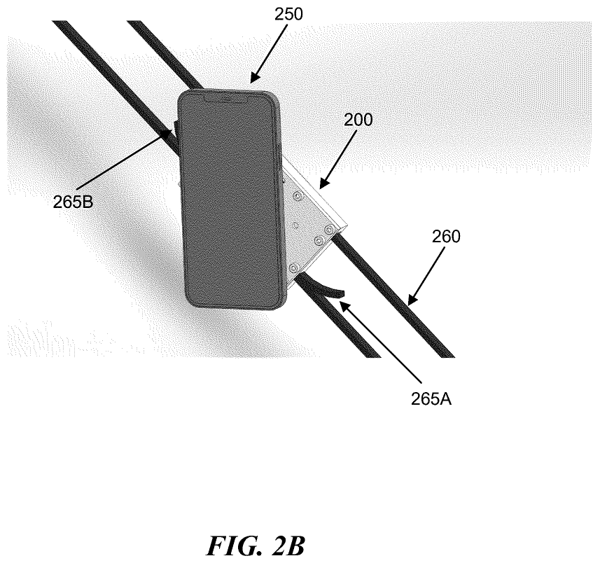

FIG. 2A illustrates an assembly of a holder component 200, according to some implementations. As illustrated in FIG. 2A, the holder component 200 can include a cover 210 and a base 220, which are bound via multiple clamps 230. The cover 210 includes multiple holes through which the clamps 230 penetrate.

The base 220 includes multiple grooves that align with the holes of the cover 210 where the clamps 230 are positioned when the cover 210 and the base 220 are bound together. The base 220 can include a straight groove 223 and a double curvature groove 226. The holder component 200 can be fixably connected to a belt having a jagged profile on one side and a flat profile on another side via the straight groove 223 and the double curvature groove 226. For example, a middle portion of the belt can be placed on the straight groove 223, and loose ends of the belt, which are looped around a pulley and a motor, respectively, can be fixed onto each other around the double curvature groove 226 via the jagged profile. In other implementations, the holder component 200 includes grooves of other shapes configured to position the belt in place.

The holder component 200 can include an adhesive component, such as suction cups 240 or an adhesive Velcro. The wireless device is attachable to the holder component 200 via the adhesive component. In some embodiments, the suction cups 240 are made of Neoprene. In some embodiments, the holder component 200 is made of materials capable of absorbing RF radiation instead of reflecting RF radiation. In instances where a first wireless device attached to the holder component 200 is located between the antenna and a second wireless device, the holder component 200 holding the first wireless device can block, but not reflect, RF radiation from traveling through the holder component 200. In other embodiments, the holder component 200, the adhesive component, and the belt are made of materials that are transparent to RF frequency being tested. However, such materials may come with limitations in that: 1) the transparent materials may not be mechanically capable of simulating multi-directional mobility of RF radiation; and/or 2) the materials may be transparent to too narrow of a range of RF frequencies to be useful for beamforming tests.

FIG. 2B illustrates a wireless device 250 attached to the holder component 200, according to some implementations. As explained in relation to FIG. 2A, the wireless device 250 can be attached to the holder component 200 via an adhesive component. The belt 260 is looped over a motor, which includes a bracket that is configured to maintain a belt tension to hold the wireless device 250 in an upright position. In some embodiments, portions of loose ends 265A-B of the belt 260, after being fixed onto each other around the double curvature groove 226 via the jagged profile, can hang outside the double curvature groove 226.

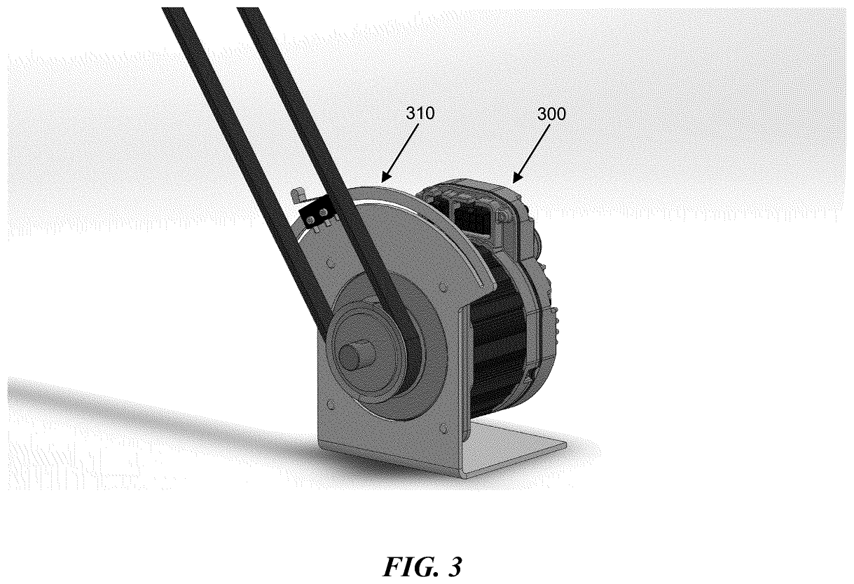

FIG. 3 is a diagram of a motor 300 that can be utilized in a belt-driven movement system, according to some implementations. The motor 300 includes a bracket 310 that can be configured to maintain a belt tension to hold a wireless device in an upright position. The motor 300 and the bracket 310 can be disposed on a wall of the RF chamber adjacent to the RAM. In some embodiments, the height of the RAM is greater than the height of the motor 300 and the bracket 310 to minimize unwanted reflections from the motor 300 and the bracket 310. The motor 300 can be communicatively coupled to an external control device to receive signals from the external control device. This eliminates the need to place a control device inside the RF chamber, reducing potential unwanted reflections generated by the control device inside the RF chamber. To this end, and without limiting the disclosed system, the motor 300 can be a stepper motor.

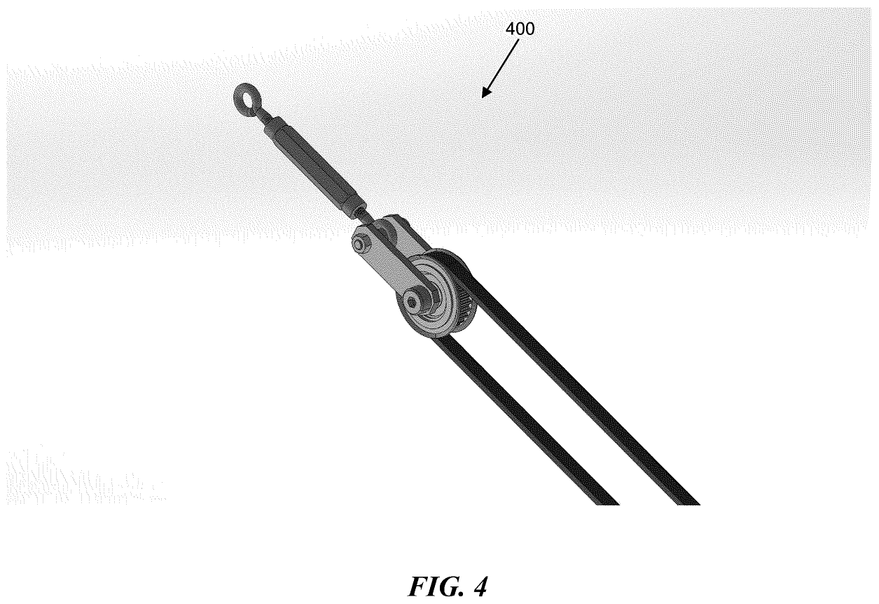

FIG. 4 is a diagram of a turnbuckle-mounted timing pulley 400 that can be utilized in a belt-driven movement system, according to some implementations. The turnbuckle-mounted timing pulley 400 is disposed on an opposite wall of the motor 300 adjacent to the RAM. A belt of the belt-driven movement system is looped over the motor 300 and the turnbuckle-mounted timing pulley 400, and the bracket 310 of the motor 300 is configured to maintain a belt tension to hold the belt and the wireless device in an upright position. More specifically, the bracket 310 can affix the motor 300 and the turnbuckle-mounted timing pulley 400 in place and provides an alignment mechanism for a switch used in homing the belt-driven movement system. The turnbuckle-mounted timing pulley 400 can be configured to provide the tension necessary to hold the belt and the wireless device in an upright position.

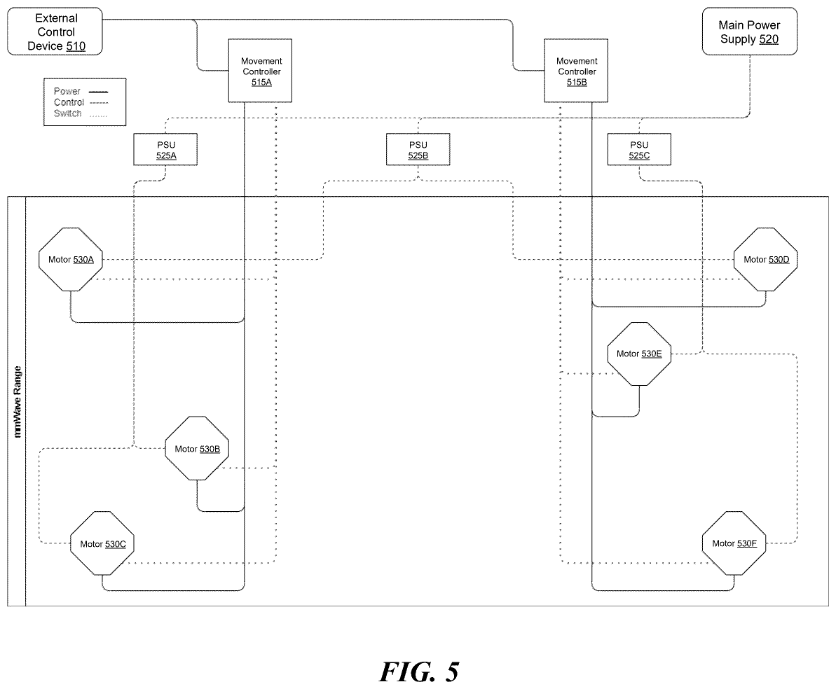

FIG. 5 is a system diagram illustrating interconnection of the belt-driven movement systems and an external control device, according to some implementations. As illustrated in FIG. 5, a computer system, such as the external control device 510, is connected to movement controllers 515A-B, and each movement controller is connected to multiple motors 530A-F of the belt-driven movement systems. The external control device 510 and the movement controllers 515A-B are located outside of the RF chamber to minimize unwanted reflections and remotely control the motors 530A-F via control signals. Each of the movement controllers 515A-B can be configured to simultaneously control the movement of one or more motors 530A-F. In other embodiments, each of the movement controllers 515A-B is configured to control the movement of a single motor of the motors 530A-F. Each of the movement controllers 515A-B can be further configured to control a position or movement of each wireless device that is placed within each belt-driven movement system. In some embodiments, the movement controllers 515A-B can include microswitches configured to control the position or movement of each wireless device.

In some embodiments, one or more switches are used along with the motors 530A-F to home the system. For example, the mechanism is driven in a single direction until it trips a switch at a point, at which the home position of the switch is set. The home position defines the 0 point for all subsequent motions. As illustrated in FIG. 5, control wiring can be used to send control signals to the motors 530A-F, whereas switch wiring is independent from control wiring and can be used to measure home positions of the motors 530A-F. In other embodiments, switches and motors can be combined to serve both functions and be considered a closed-loop control system.

The belt-driven movement systems are powered by a main power supply 520. In an embodiment, as illustrated in FIG. 5, the main power supply 520 supplies power to multiple power supply units (PSU) 525A-C, each of which supplies power to one or more motors 530A-F. To this end, and without limiting the disclosed system, the PSU 525A-C can be IPC-5 power supplies that deliver low voltage power optimized to power the motors 530A-F.

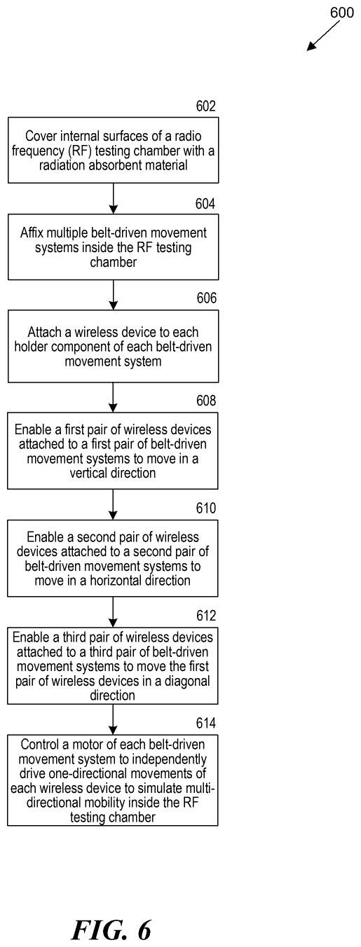

FIG. 6 is a flowchart illustrating a representative process 600 to drive one-directional movements of wireless devices to simulate multi-directional mobility inside the RF chamber, according to some implementations. Other implementations of the process 600 include additional, fewer, or different processes or include performing processes in different orders.

At 602, internal surfaces of a radio frequency (RF) testing chamber are covered with a radiation absorbent material. The radiation absorbent material can be arrays of pyramid-shaped pieces, each of which is constructed with lossy dielectric material to minimize RF reflection inside the RF testing chamber.

At 604, multiple belt-driven movement systems are affixed inside the RF testing chamber. Each belt-driven movement system of the multiple belt-driven movement systems includes a belt that traverses across the RF testing chamber and a holder component that is connected to the belt. In some embodiments, at least three pairs of belt-driven movement systems are affixed inside the chamber, including a first pair of belt-driven movement systems that are vertically oriented relative to a floor of the RF testing chamber, a second pair of belt-driven movement systems that are horizontally oriented relative to the floor of the RF testing chamber, and a third pair of belt-driven movement systems that are diagonally oriented relative to the floor of the RF testing chamber. In other embodiments, at least two belt-driven movement systems are affixed inside the chamber, including a first belt-driven movement system that has a first orientation and a second belt-driven movement system that has a second orientation that is different from the first orientation.

In some embodiments, affixing each belt-driven movement system inside the RF testing chamber comprises looping a belt around a turnbuckle-mounted timing pulley and a motor. The turnbuckle-mounted timing pulley can be disposed on a wall of the RF testing chamber adjacent to the radiation absorbent material. The motor can be disposed on an opposite wall of the turnbuckle-mounted timing pulley adjacent to the radiation absorbent material. The motor can include a bracket that is configured to maintain a belt tension.

At 606, a wireless device is attached to a holder component of each of the multiple belt-driven movement systems. The wireless device can be attached to the holder component via an adhesive component. The adhesive component can be a suction cup made of materials such as Neoprene or an adhesive Velcro. The motor, together with the bracket, can be configured to maintain a belt tension to hold each wireless device in an upright position.

At 608, a pair of wireless devices attached to a pair of belt-driven movement systems oriented vertically is enabled to move in a vertical direction. At 610, a pair of wireless devices attached to a pair of belt-driven movement systems oriented horizontally is enabled to move in a horizontal direction. At 612, a pair of wireless devices attached to a pair of belt-driven movement systems oriented diagonally is enabled to move in a diagonal direction.

In other embodiments, a first wireless device attached to a first belt-driven movement system in a first orientation is enabled to move along the first orientation. A second wireless device attached to a second belt-driven movement system in a second orientation that is different from the first orientation is enabled to move along the second orientation.

At 614, a motor of each of the multiple belt-driven movement systems is configured to independently drive one-directional movements of each wireless device to simulate multi-directional mobility inside the RF testing chamber. In some embodiments, each motor is communicatively coupled to an external control device and receives a control signal from the external device. The control signal can include speed and direction information for controlling each motor. The control signal can also include calibration information to calibrate belt tension for each belt.

### Computer System

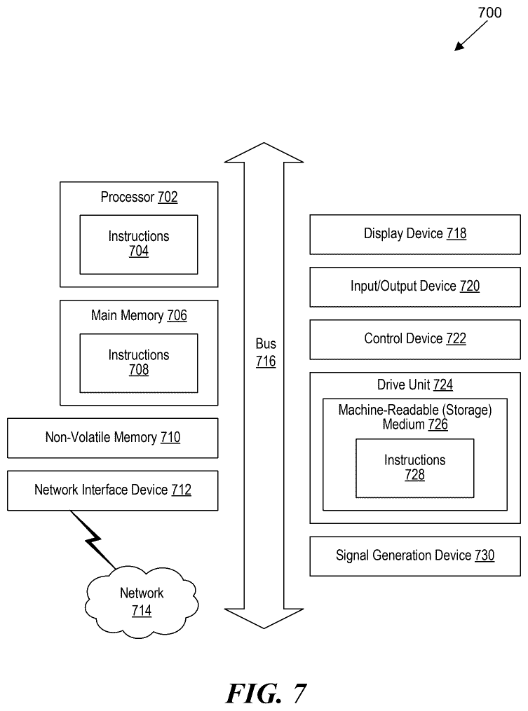

FIG. 7 is a block diagram that illustrates an example of a computer system 700 in which at least some operations described herein can be implemented. As shown, the computer system 700 can include: one or more processors 702, main memory 706, non-volatile memory 710, a network interface device 712, a video display device 718, an input/output device 720, a control device 722 (e.g., keyboard and pointing device), a drive unit 724 that includes a machine-readable (storage) medium 726, and a signal generation device 730 that are communicatively connected to a bus 716. The bus 716 represents one or more physical buses and/or point-to-point connections that are connected by appropriate bridges, adapters, or controllers. Various common components (e.g., cache memory) are omitted from FIG. 7 for brevity. Instead, the computer system 700 is intended to illustrate a hardware device on which components illustrated or described relative to the examples of the figures and any other components described in this specification can be implemented.

The computer system 700 can take any suitable physical form. For example, the computing system 700 can share a similar architecture as that of a server computer, personal computer (PC), tablet computer, mobile telephone, game console, music player, wearable electronic device, network-connected (“smart”) device (e.g., a television or home assistant device), AR/VR systems (e.g., head-mounted display), or any electronic device capable of executing a set of instructions that specify action(s) to be taken by the computing system 700. In some implementations, the computer system 700 can be an embedded computer system, a system-on-chip (SOC), a single-board computer system (SBC), or a distributed system such as a mesh of computer systems, or it can include one or more cloud components in one or more networks. Where appropriate, one or more computer systems 700 can perform operations in real time, in near real time, or in batch mode.

The network interface device 712 enables the computing system 700 to mediate data in a network 714 with an entity that is external to the computing system 700 through any communication protocol supported by the computing system 700 and the external entity. Examples of the network interface device 712 include a network adapter card, a wireless network interface card, a router, an access point, a wireless router, a switch, a multilayer switch, a protocol converter, a gateway, a bridge, a bridge router, a hub, a digital media receiver, and/or a repeater, as well as all wireless elements noted herein.

The memory (e.g., main memory 706, non-volatile memory 710, machine-readable medium 726) can be local, remote, or distributed. Although shown as a single medium, the machine-readable medium 726 can include multiple media (e.g., a centralized/distributed database and/or associated caches and servers) that store one or more sets of instructions 728. The machine-readable medium 726 can include any medium that is capable of storing, encoding, or carrying a set of instructions for execution by the computing system 700. The machine-readable medium 726 can be non-transitory or comprise a non-transitory device. In this context, a non-transitory storage medium can include a device that is tangible, meaning that the device has a concrete physical form, although the device can change its physical state. Thus, for example, non-transitory refers to a device remaining tangible despite this change in state.

Although implementations have been described in the context of fully functioning computing devices, the various examples are capable of being distributed as a program product in a variety of forms. Examples of machine-readable storage media, machine-readable media, or computer-readable media include recordable-type media such as volatile and non-volatile memory 710, removable flash memory, hard disk drives, optical disks, and transmission-type media such as digital and analog communication links.

In general, the routines executed to implement examples herein can be implemented as part of an operating system or a specific application, component, program, object, module, or sequence of instructions (collectively referred to as “computer programs”). The computer programs typically comprise one or more instructions (e.g., instructions 704, 708, 728) set at various times in various memory and storage devices in computing device(s). When read and executed by the processor 702, the instruction(s) cause the computing system 700 to perform operations to execute elements involving the various aspects of the disclosure.

### Remarks

The terms “example,” “embodiment,” and “implementation” are used interchangeably. For example, references to “one example” or “an example” in the disclosure can be, but not necessarily are, references to the same implementation; and such references mean at least one of the implementations. The appearances of the phrase “in one example” are not necessarily all referring to the same example, nor are separate or alternative examples mutually exclusive of other examples. A feature, structure, or characteristic described in connection with an example can be included in another example of the disclosure. Moreover, various features are described that can be exhibited by some examples and not by others. Similarly, various requirements are described that can be requirements for some examples but not for other examples.

The terminology used herein should be interpreted in its broadest reasonable manner, even though it is being used in conjunction with certain specific examples of the invention. The terms used in the disclosure generally have their ordinary meanings in the relevant technical art, within the context of the disclosure, and in the specific context where each term is used. A recital of alternative language or synonyms does not exclude the use of other synonyms. Special significance should not be placed upon whether or not a term is elaborated or discussed herein. The use of highlighting has no influence on the scope and meaning of a term. Further, it will be appreciated that the same thing can be said in more than one way.

Unless the context clearly requires otherwise, throughout the description and the claims, the words “comprise,” “comprising,” and the like are to be construed in an inclusive sense, as opposed to an exclusive or exhaustive sense—that is to say, in the sense of “including, but not limited to.” As used herein, the terms “connected,” “coupled,” and any variants thereof mean any connection or coupling, either direct or indirect, between two or more elements; the coupling or connection between the elements can be physical, logical, or a combination thereof. Additionally, the words “herein,” “above,” “below,” and words of similar import can refer to this application as a whole and not to any particular portions of this application. Where context permits, words in the above Detailed Description using the singular or plural number may also include the plural or singular number, respectively. The word “or” in reference to a list of two or more items covers all of the following interpretations of the word: any of the items in the list, all of the items in the list, and any combination of the items in the list. The term “module” refers broadly to software components, firmware components, and/or hardware components.

While specific examples of technology are described above for illustrative purposes, various equivalent modifications are possible within the scope of the invention, as those skilled in the relevant art will recognize. For example, while processes or blocks are presented in a given order, alternative implementations can perform routines having steps, or employ systems having blocks, in a different order, and some processes or blocks may be deleted, moved, added, subdivided, combined, and/or modified to provide alternative or sub-combinations. Each of these processes or blocks can be implemented in a variety of different ways. Also, while processes or blocks are at times shown as being performed in series, these processes or blocks can instead be performed or implemented in parallel or can be performed at different times. Further, any specific numbers noted herein are only examples such that alternative implementations can employ differing values or ranges.

Details of the disclosed implementations can vary considerably in specific implementations while still being encompassed by the disclosed teachings. As noted above, particular terminology used when describing features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific examples disclosed herein, unless the above Detailed Description explicitly defines such terms. Accordingly, the actual scope of the invention encompasses not only the disclosed examples but also all equivalent ways of practicing or implementing the invention under the claims. Some alternative implementations can include additional elements to those implementations described above or include fewer elements.

Any patents and applications and other references noted above, and any that may be listed in accompanying filing papers, are incorporated herein by reference in their entireties, except for any subject matter disclaimers or disavowals, and except to the extent that the incorporated material is inconsistent with the express disclosure herein, in which case the language in this disclosure controls. Aspects of the invention can be modified to employ the systems, functions, and concepts of the various references described above to provide yet further implementations of the invention.

To reduce the number of claims, certain implementations are presented below in certain claim forms, but the applicant contemplates various aspects of an invention in other forms. For example, aspects of a claim can be recited in a means-plus-function form or in other forms, such as being embodied in a computer-readable medium. A claim intended to be interpreted as a means-plus-function claim will use the words “means for.” However, the use of the term “for” in any other context is not intended to invoke a similar interpretation. The applicant reserves the right to pursue such additional claim forms either in this application or in a continuing application.

1. A system configured to simulate mobility of a wireless device inside a radio frequency (RF) testing chamber, the system comprising:
a radiation absorbent material; and
a belt-driven movement system for each wireless device, wherein the belt-driven movement system includes:
a belt having a middle portion and loose ends, wherein the belt includes a jagged profile on one side and a flat profile on another side;
a holder component fixably connected to the belt, the holder component including a straight groove and a double curvature groove,
wherein a middle portion of the belt is placed on the straight groove and the loose ends of the belt are fixed onto each other around the double curvature groove via the jagged profile, and
wherein the wireless device is attachable to the holder component;
a turnbuckle-mounted timing pulley over which the belt is looped,
wherein the turnbuckle-mounted timing pulley is disposed on a wall of the RF testing chamber adjacent to the radiation absorbent material; and
a motor over which the belt is looped,
wherein the motor is disposed on an opposite wall of the turnbuckle-mounted timing pulley adjacent to the radiation absorbent material and drives one-directional movement of the belt,
wherein the motor includes a bracket configured to maintain a belt tension to hold the wireless device in an upright position, and
wherein the motor is communicatively coupled to an external control device.

2. The system of claim 1, wherein the radiation absorbent material covers internal surfaces of the RF testing chamber.

3. The system of claim 1, wherein the motor is a stepper motor.

4. The system of claim 1, wherein the motor is configured to receive a control signal from the external control device, wherein the control signal includes calibration information to maintain the belt tension.

5. The system of claim 1, wherein the system includes at least six wireless devices.

6. The system of claim 1, wherein the holder component further comprises:
a suction cup or an adhesive Velcro via which the wireless device is attachable to the holder component.

7. The system of claim 6, wherein the suction cup is made of Neoprene.

8. The system of claim 1 further comprising:
a first belt oriented horizontally relative to a floor of the RF testing chamber;
a second belt oriented vertically relative to the floor of the RF testing chamber; and
a third belt oriented diagonally relative to the floor of the RF testing chamber.

9. The system of claim 1 further comprising:
a first belt with a first orientation; and
a second belt with a second orientation that is different from the first orientation.

10. The system of claim 1 further comprising:
a microswitch that is configured to control a movement of the wireless device.

11. A method to simulate movement of multiple wireless devices inside a radio frequency (RF) testing chamber, the method comprising:
covering internal surfaces of the RF testing chamber with a radiation absorbent material;
affixing multiple belt-driven movement systems inside the RF testing chamber,
wherein each belt-driven movement system has a belt that traverses across the RF testing chamber and a holder component connected to the belt,
wherein a first pair of belt-driven movement systems are vertically oriented relative to a floor of the RF testing chamber,
wherein a second pair of belt-driven movement systems are horizontally oriented relative to the floor of the RF testing chamber, and
wherein a third pair of belt-driven movement systems are diagonally oriented relative to the floor of the RF testing chamber;
attaching a wireless device to each holder component of each belt-driven movement system;
enabling a first pair of wireless devices attached to the first pair of belt-driven movement systems that are vertically oriented to move in a vertical direction relative to the floor of the RF testing chamber;
enabling a second pair of wireless devices attached to the second pair of belt-driven movement systems that are horizontally oriented to move in a horizontal direction relative to the floor of the RF testing chamber;
enabling a third pair of wireless devices attached to the third pair of belt-driven movement systems that are diagonally oriented to move in a diagonal direction relative to the floor of the chamber; and
controlling a motor of each belt-driven movement system to independently drive one-directional movements of each wireless device to simulate multi-directional mobility inside the RF testing chamber.

12. The method of claim 11, wherein attaching the wireless device to each holder component of each belt-driven movement system is performed via a suction cup or adhesive Velcro.

13. The method of claim 11, wherein controlling a motor of each belt-driven movement system further comprises:
receiving a control signal from an external control device; and
controlling, based on the received control signal, a direction and a speed of each belt of the multiple belt-driven movement systems.

14. The method of claim 11, further comprising:
calibrating a belt tension for each belt of the multiple belt-driven movement systems to hold each wireless device in an upright position.

15. The method of claim 11, wherein affixing multiple belt-driven movement systems inside the RF testing chamber further comprises:
for each belt-driven movement system, looping the belt around a turnbuckle-mounted timing pulley and the motor,
wherein the turnbuckle-mounted timing pulley is disposed on a wall of the RF testing chamber adjacent to the radiation absorbent material, and
wherein the motor is disposed on an opposite wall of the turnbuckle-mounted timing pulley adjacent to the radiation absorbent material and drives one-directional movement of the belt.

16. A method to simulate movement of multiple wireless devices inside a radio frequency (RF) testing chamber, the method comprising:
covering internal surfaces of the RF testing chamber with a radiation absorbent material;
affixing multiple belt-driven movement systems inside the RF testing chamber,
wherein each belt-driven movement system has a belt that traverses across the RF testing chamber and a holder component connected to the belt,
wherein a first belt-driven movement system has a first orientation, and
wherein a second belt-driven movement system has a second orientation that is different from the first orientation;
attaching a wireless device to each holder component of each belt-driven movement system;
enabling a first wireless device attached to the first belt-driven movement system with the first orientation to move along the first orientation;
enabling a second wireless device attached to the second belt-driven movement system with the second orientation to move along the second orientation; and
controlling a motor of each belt-driven movement system to independently drive one-directional movements of each wireless device to simulate multi-directional mobility inside the RF testing chamber.

17. The method of claim 16, wherein attaching the wireless device to each holder component of each belt-driven movement system is performed via a suction cup or adhesive Velcro.

18. The method of claim 16, wherein controlling a motor of each belt-driven movement system further comprises:
receiving a control signal from an external control device; and
controlling, based on the received control signal, a direction and a speed of each belt of the multiple belt-driven movement systems.

19. The method of claim 16, further comprising:
calibrating a belt tension for each belt of the multiple belt-driven movement systems to hold each wireless device in an upright position.

20. The method of claim 16, wherein affixing multiple belt-driven movement systems inside the RF testing chamber further comprises:
for each belt-driven movement system, looping the belt around a turnbuckle-mounted timing pulley and the motor,
wherein the turnbuckle-mounted timing pulley is disposed on a wall of the RF testing chamber adjacent to the radiation absorbent material, and
wherein the motor is disposed on an opposite wall of the turnbuckle-mounted timing pulley adjacent to the radiation absorbent material and drives one-directional movement of the belt.
